(19) United States
(12) Patent Application Publication
(10) Pub. No.: US 2021/0134620 A1
(43) Pub. Date: May 6, 2021

(54) SUPPORTING UNIT, APPARATUS HAVING THE SAME AND METHOD FOR TREATING SUBSTRATE USING THE SAME

(71) Applicant: SEMES CO., LTD., Chungcheongnam-do (KR)

(72) Inventors: Seunghan LEE, Chungcheongnam-do (KR); Jong Seok SEO, Chungcheongnam-do (KR); Euntark LEE, Chungcheongnam-do (KR); Jaeoh BANG, Seoul (KR); Sukhwan CHI, Gyeonggi-do (KR)

(21) Appl. No.: 17/088,143

(22) Filed: Nov. 3, 2020

(30) Foreign Application Priority Data
Nov. 4, 2019 (KR) 10-2019-0139678

(51) Int. Cl. H01L 21/67; H05B 1/02; F27B 17/00; F27D 5/00; H05B 3/22; G03F 7/16

(52) U.S. Cl. CPC H01L 21/67103; H05B 1/0233; F27B 17/0025; F27D 2009/0008; H05B 3/22; G03F 7/162; G03F 7/168; F27D 5/0037

(57) ABSTRACT

Embodiments of the inventive concept provides an apparatus for treating a substrate. An embodiment of the inventive concept comprises a housing having a process space therein; and a supporting unit supporting a substrate in the process space, and the supporting unit comprises a supporting plate supporting the substrate; a heater member provide in the supporting plate and heating the substrate; and a cooling unit provided below the heater member and cooling the supporting plate, the cooling unit comprises a cooling plate spaced apart from the heater member; and a nozzle provided in the cooling plate, and supplying a cooling gas to a bottom surface of the heater member; and a driver moving the cooling plate between a standby position spaced a first distance apart from the heater member and a cooling position spaced a second distance apart from the heater member, the second distance is shorter than the first distance.

### CROSS-REFERENCE TO RELATED APPLICATIONS

A claim for priority under 35 U.S.C. § 119 is made to Korean Patent Application No. 10-2019-0139678 filed on Nov. 4, 2019, in the Korean Intellectual Property Office, the entire contents of which are hereby incorporated by reference.

### BACKGROUND

Embodiments of the inventive concept described herein relates to a supporting unit heat-treating a substrate and a substrate treating apparatus comprising the same and a method for treating a substrate using the same.

In general, to manufacture a semiconductor device, various processes, such as cleaning, depositing, photographing, and ion implanting processes are performed. Among the above processes, a photographing process comprises a process forming a liquid-film such as photoresist on the substrate.

After forming the liquid-film, a bake process heating the substrate is performed. The bake process is performed in temperature much higher than room temperature, and a heater heating the substrate is used for this process.

A chamber performing the bake process heats the substrate using different temperature depending on the substrate. For example, the bake chamber treats a preceding substrate with a first temperature in the bake chamber, and then the bake chamber treats a subsequent substrate carried thereinto with a second temperature lower than the first temperature. Herein, after treating the preceding substrate with the first temperature, a cooling process cooling the heater is required for treating the subsequent substrate with the second temperature lower than the first temperature.

In general, in the cooling process, a cooling gas is supplied toward the heater to cool the heater. When spraying the cooling gas, a flow rate of the cooling gas affects a cooling efficiency. Under the same spray amount, the longer a gas supplying nozzle, the faster the flow velocity. For obtaining the faster flow velocity, the longer nozzle and consequently the higher bake chamber should be provided.

### SUMMARY

Embodiments of the inventive concept provide a substrate treating apparatus and a method for treating the substrate when a heating unit is cooled.

Embodiments of the inventive concept provide a substrate treating apparatus and a method for treating the substrate that can secure a flow rate of a cooling gas used for cooling a heating unit.

The objects which will be achieved in the inventive concept are not limited to the above, but other objects, which are not mentioned, will be apparently understood to those skilled in the art.

Embodiments of the inventive concept provides an apparatus for treating a substrate. In one exemplary embodiment of the inventive concept, a substrate treating apparatus comprises a housing having a process space therein and a supporting unit supporting a substrate in the process space, and the supporting unit comprises a supporting plate supporting the substrate, a heater member provided in the supporting plate and heating the substrate, and a cooling unit provided below the heater member and cooling the supporting plate, the cooling unit comprises a cooling plate spaced apart from the heater member, a nozzle provided in the cooling plate, and supplying a cooling gas to a bottom surface of the heater member, and a driver moving the cooling plate between a standby position spaced a first distance apart from the heater member and a cooling position spaced a second distance apart from the heater member, the second distance is shorter than the first distance.

According to an embodiment of the inventive concept, the cooling plate overlaps with the heater member in the standby position and the cooling position when viewed from above.

According to an embodiment of the inventive concept, the cooling plate has a mounting groove on an upper surface and the nozzle is arranged in the mounting groove.

According to an embodiment of the inventive concept, the cooling unit further comprises a gas supply member supplying the cooling gas into the mounting groove.

According to an embodiment of the inventive concept, the driver is provided in a motor.

According to an embodiment of the inventive concept, the driver is provided in a cylinder.

Further, the inventive concept provides a method for treating a substrate. An embodiment of the inventive concept comprises a first heating step that the supporting plate heats a substrate at a first temperature and a cooling step that the cooling gas is supplied to the supporting plate for cooling the supporting plate to predetermined temperature, and the cooling plate moves toward the heater member and to cool the heater member in the cooling step.

An embodiment of the inventive concept further comprises a second heating step that the supporting plate heats the substrate at a second temperature after the cooling step.

According to an embodiment of the inventive concept, the second temperature is lower than the first temperature.

According to an embodiment of the inventive concept, the cooling plate locates in a standby position spaced a first distance apart from the heater member in the first heating step, and a cooling position spaced a second distance apart from the heater member in the cooling step, and the second distance is shorter than the first distance.

According to an embodiment of the inventive concept, cooling efficiency can be increased when a heating unit is cooled.

According to an embodiment of the inventive concept, a flow rate of the cooling gas used for cooling the heating unit can be secured.

The inventive concept and methods of accomplishing the same may be understood more readily by reference to the following detailed description of embodiments and the accompanying drawings. However, the inventive concept may be embodied in many different forms, and should not be construed as being limited to the embodiments set forth herein. Rather, these embodiments are provided so that this inventive concept will be thorough and complete and will fully convey the concept of the invention to those skilled in the art, and the inventive concept will only be defined by the appended claims.

### BRIEF DESCRIPTION OF THE FIGURES

FIG. 1 is a perspective view schematically showing a substrate treating apparatus, according to an embodiment of the inventive concept.

FIG. 2 is a sectional view of a substrate treating apparatus, which shows a coating block or a developing block of FIG. 1.

FIG. 3 is a plan view showing the substrate treating apparatus of FIG. 1.

FIG. 4 shows an example of a hand of a transferring robot of FIG. 3.

FIG. 5 is a plan view schematically showing a heat treating chamber of FIG. 3.

FIG. 6 is a front view showing the heat treating chamber of FIG. 5.

FIG. 7 is a cross-sectional view showing a heating apparatus of FIG. 6.

FIG. 8 is a plan view and FIG. 9 is a perspective view which show a substrate supporting unit of FIG. 7.

FIG. 10 is a plan view showing a cooling plate according to an embodiment of the inventive concept.

FIG. 11 is a flow chart showing a method for treating a substrate according to an embodiment of the inventive concept.

FIG. 12 and FIG. 13 are a cross-sectional view respectively showing a cooling plate according to an embodiment of the inventive concept.

### DETAILED DESCRIPTION

Hereinafter, an embodiment of the inventive concept will be described in more detail with reference to the accompanying drawings. The embodiments of the inventive concept may be modified in various forms, and the scope of the inventive concept should not be construed to be limited by the embodiments of the inventive concept described in the following. The embodiments of the inventive concept are provided to describe the inventive concept for those skilled in the art more completely. Accordingly, the shapes of the components in the drawings are exaggerated to emphasize clearer descriptions.

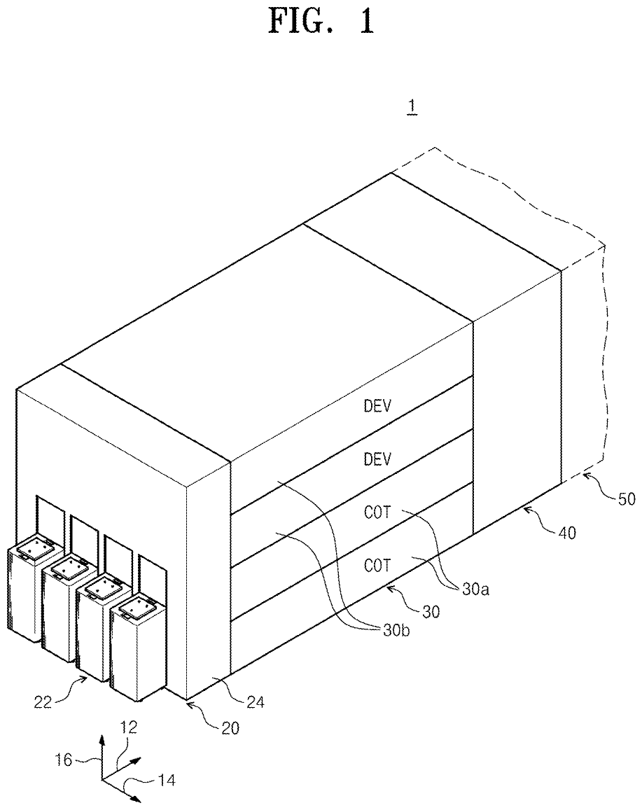

Referring to FIG. 1 to FIG. 3, a substrate treating apparatus 1 comprises an index module 20, a treating module 30, and an interface module 40. According to an embodiment, the index module 20, the treating module 30, and the interface module 40 are sequentially aligned in line. Hereinafter, a direction in which the index module 20, the treating module 30, and the interface module 40 are arranged will be referred to as a first direction 12, a direction that is perpendicular to the first direction 12 when viewed from above will be referred to as a second direction 14, and a direction perpendicular to all the first direction 12 and the second direction 14 will be referred to as a third direction 16.

The index module 20 transfers a substrate ‘W’ to the treating module 30 from a container 10, and the index module 20 transfers the completely treated substrate ‘W’ to the container 10. The longitudinal direction of the index module 20 is provided in the second direction 14. The index module 20 has a load port 22 and an index frame 24. The load port 22 is positioned at an opposite side of the treating module 30, based on the index frame 24. The container 10 having substrates ‘W’ is placed on the load port 22. A plurality of load ports 22 may be provided and may be arranged along the second direction 14.

The container 10 may be a container 10 for sealing such as a Front Open Unified Pod (FOUP). The container 10 may be placed on the load port 22 by a transport unit (not shown) such as Overhead Transfer, Overhead Conveyor, or Automatic Guided Vehicle, or by a worker.

An index robot 2200 is provided inside the index frame 24. A guide rail 2300, which has a longitudinal direction provided in the second direction 14, may be provided in the index frame 24, and the index robot 2200 may be provided to be movable on the guide rail 2300. The index robot 2200 may comprise a hand 2220 in which the substrate ‘W’ is positioned, and the hand 2220 may be provided to be movable forward and backward, rotatable about the third direction 16, and movable along the third direction 16.

The treating module 30 performs a coating process and a developing process with respect to the substrate ‘W’. The treating module 30 has a coating block 30a and a developing block 30b. The coating block 30a performs the coating process with respect to the substrate ‘W’, and the developing block 30b performs the developing process with respect to the substrate ‘W’. A plurality of coating blocks 30a are provided and stacked on each other. A plurality of developing blocks 30b are provided, and stacked on each other. According to an embodiment of FIG. 1, two coating blocks 30a are provided and two developing blocks 30b are provided. The coating blocks 30a may be disposed under the developing blocks 30b. According to an example, two coating blocks 30a may be perform the same process and may be provided in the same structure. In addition, two developing blocks 30a may be perform the same process and may be provided in the same structure.

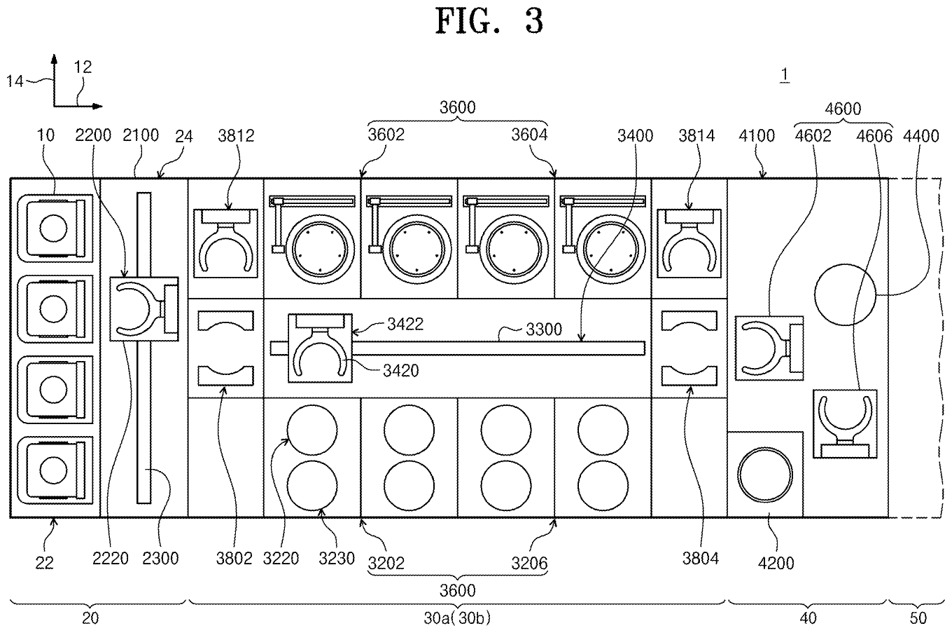

Referring to FIG. 3, the coating block 30a has a heat treating chamber 3200, a transferring chamber 3400, a liquid treating chamber 3600, and a buffer chamber 3800. The heat treating chamber 3200 performs a heat treating process with respect to the substrate ‘W’. The heat treating process may comprise a cooling process and a heating process. The liquid treating chamber 3600 supplies a liquid onto the substrate ‘W’ to form a liquid film. The liquid film may be a photoresist film or an anti-reflective film. The transferring chamber 3400 transfers the substrate ‘W’ between the heat treating chamber 3200 and the liquid treating chamber 3600 inside the coating block 30a.

The transferring chamber 3400 has a longitudinal direction parallel to the first direction 12. The transferring robot 3422 is provided in the transferring chamber 3400. The transferring robot 3422 transfers the substrate ‘W’ among the heat treating chamber 3200, the liquid treating chamber 3600, and the buffer chamber 3800. According to an example, the transferring robot 3422 may comprise a hand 3420 in which the substrate ‘W’ is positioned, and the hand 3420 may be provided to be movable forward and backward, rotatable about the third direction 16, and movable along the third direction 16. A guide rail 3300, which has a longitudinal direction parallel to the second direction 12, is provided in the transferring chamber 3400, and the transferring robot 3422 may be provided to be movable on the guide rail 3300.

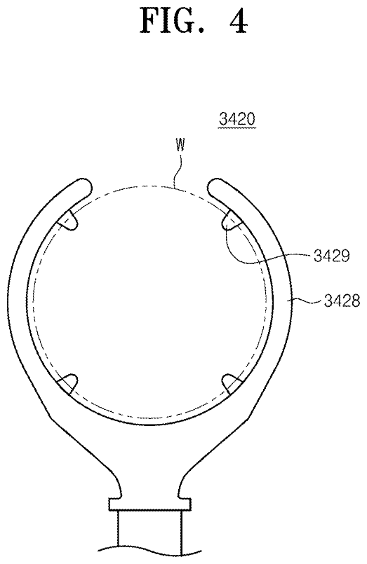

FIG. 4 shows an example of the hand of a transferring unit of FIG. 3. Referring to FIG. 4, the hand 3420 has a base 3428 and a supporting protrusion 3429. The base 3428 may have an annular ring shape in which a part of the circumference is bent. The base 3428 has an inner diameter greater than a diameter of the substrate ‘W’. The supporting protrusion 3429 extends inward from base 3428. A plurality of supporting protrusions 3429 are provided to support an edge area of the substrate ‘W’. According to an example, four supporting protrusions 3429 may be provided at equal distances.

A plurality of heat treating chambers 3200 are provided. Referring to FIG. 3 and FIG. 4, the heat treating chambers 3200 are arranged along the first direction 12. The heat treating chambers 3200 are positioned at one side of the transferring chamber 3400.

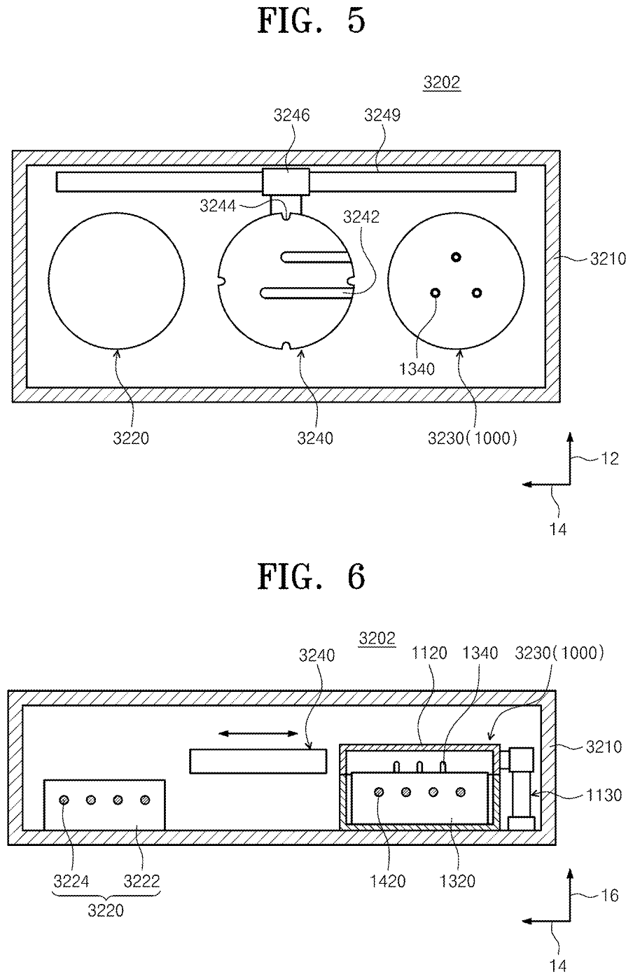

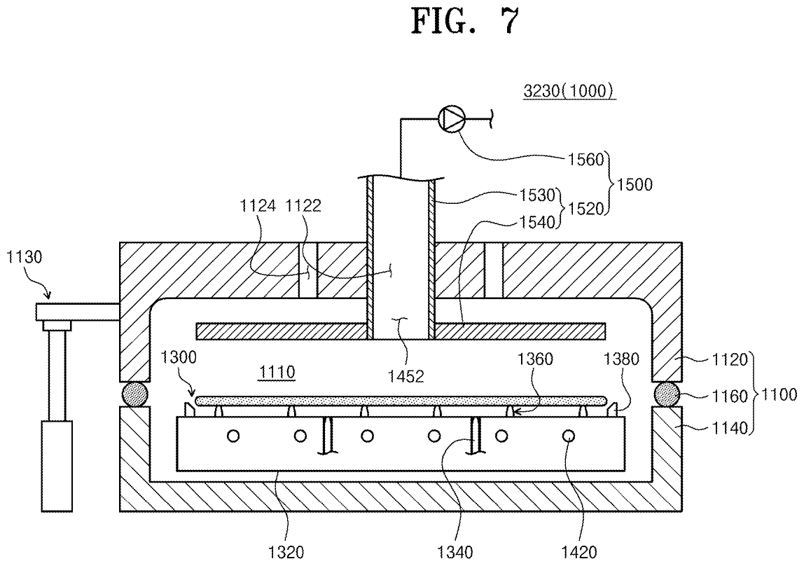

FIG. 5 is a plan view schematically showing an example of the heat treating chamber of FIG. 3, and FIG. 6 is a front view showing the heat treating chamber of FIG. 5. The heat treating chamber 3200 has a housing 3210, a cooling apparatus 3220, a heating apparatus 3230, and a transferring plate 3240.

The housing 3210 has a substantially rectangular parallelepiped shape. The housing 3210 defines an entrance (not shown) in a sidewall to introduce or withdraw the substrate ‘W’. The entrance may be maintained in an open state. A door (not shown) may be provided to selectively open or close the entrance. The cooling apparatus 3220, the heating apparatus 3230, and the transferring plate 3240 are provided inside the housing 3210. The cooling apparatus 3220 and the heating apparatus 3230 are provided in parallel along the second direction 14. According to an embodiment, the cooling apparatus 3220 may be positioned more closely to the transferring chamber 3400 than the heating apparatus 3230.

The cooling apparatus 3220 has a cooling plate 3222. The cooling plate 3222 may have a substantially circular shape when viewed from above. The cooling plate 3222 has a cooling member 3224. According to an embodiment, the cooling member 3224 may be formed inside the cooling plate 3222 to serve as a fluid passage through which a cooling fluid flows.

The heating unit 3230 is provided in a heating unit 1000 that heats the substrate ‘W’ to a temperature higher than room temperature. The heating apparatus 3230 heats the substrate ‘W’ at an atmosphere having atmospheric pressure or lower.

The transferring plate 3240 is provided in the shape of a substantially disk plate, and has a diameter corresponding to that of the substrate ‘W’. A notch 3244 is formed in an edge of the transferring plate 3240. The notch 3244 may have a shape corresponding to the protrusion 3429 formed on the hand 3420 of the described transferring robots 3422, 3424. In addition, notches 3244 may be provided in number corresponding to the number of protrusions 3429 formed in the hand 3420, and may be formed at positions corresponding to those of the protrusions 3429. When the vertical positions of the hand 3420 and the transferring plate 3240 are changed in the state that the hand 3420 and the transferring plate 3240 are aligned in the vertical direction, the substrate ‘W’ is transferred between the hand 3420 and the transferring plate 3240. The transferring plate 3240 may be mounted on a guide rail 3249, and may move along the guide rail 3249 by the driver 3246. A plurality of guide grooves 3242 are provided in the shape of a slit in the transferring plate 3240. The guide groove 3242 extends inward from an end portion of the transferring plate 3240. The longitudinal direction of the guide groove 3242 is provided along the second direction 14, and the guide grooves 3242 are positioned to be spaced apart from each other along the first direction 12. The guide groove 3242 prevents an interference between the transferring plate 3240 and a lift pin 1340 when the substrate ‘W’ is transferred between the transferring plate 3240 and the heating apparatus 3230.

A heating of the substrate ‘W’ is performed while the substrate ‘W’ is placed directly on the supporting plate 1320, and a cooling of the substrate ‘W’ is performed while the transferring plate 3240 on which the substrate ‘W’ is placed is in contact with the cooling plate 3222. The transfer plate 3240 is provide in a material having a high heat conductivity so that heat transfer is well performed between the cooling plate 3222 and the substrate ‘W’. According to an example, the transferring plate 3240 may be provided in a metal material.

The heating apparatus 3230 provided in a part of heat treating chambers 3200 can supply gas during a heating of the substrate ‘W’ to improve an attachment rate of the photoresist to the substrate ‘W’. According to an example, gas may be hexamethyldisilane gas.

A plurality of liquid treating chambers 3600 are provided. Some of the liquid treating chambers 3600 may be provided to be stacked on each other. The liquid treating chambers 3600 are positioned at the other side of the transferring chamber 3400, opposite the heat treating chambers 3200. The liquid treating chambers 3600 are arranged in line along the first direction 12. Some of the liquid treating chambers 3600 are provided in a position adjacent to the index module 20. Hereinafter, these liquid treating chambers 3602 are referred to as front liquid treating chambers. Others of the liquid treating chambers 3600 are provided in a position adjacent to the interface module 40. Hereinafter, these liquid treating chambers are referred to as rear liquid treating chambers 3604.

A first liquid is coated on the substrate ‘W’ in the front liquid treating chamber 3602, and a second liquid is coated on the substrate ‘W’ in the rear liquid treating chamber 3604. The first liquid may be different from the second liquid. According to an example, the first liquid is to form an anti-reflective film, and the second liquid is to form a photoresist. The photoresist may be coated on the substrate ‘W’ having pre-formed anti-reflective film. Alternatively, the first liquid may be photoresist and the second liquid may be for an anti-reflective film. In this case, the anti-reflective film may be coated onto the substrate ‘W’ coated with photoresist. Alternatively, the first liquid and the second liquid may be the same type of liquids, and all the first liquid and the second liquid may be photoresist.

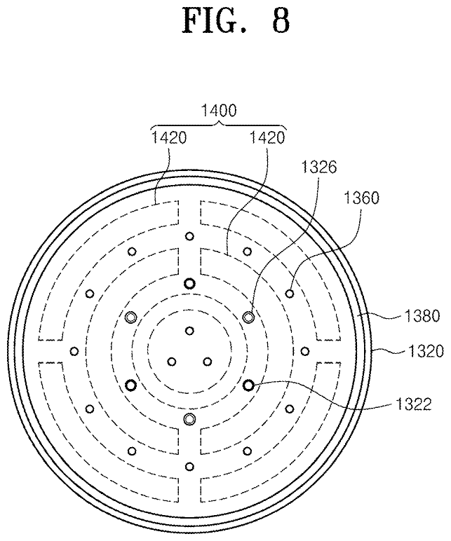

FIG. 7 is a cross-sectional view showing the heating apparatus of FIG. 6. Referring to FIG. 7, the heating unit 1000 comprises a housing 1100, a supporting unit 1300, and an exhaust unit 1500.

The housing 1100 provides a treating space 1110 therein for heat treating the substrate ‘W’. The treating space 1110 is provided to be isolated from the outside. The housing 1100 comprises an upper body 1120, a lower body 1140, and a sealing member 1160.

The upper body 1120 is provided in a cylindrical shape with an opened lower portion. An exhaust hole 1122 and an inflow hole 1124 are formed on an upper surface of the upper body 1120. The exhaust hole 1122 is formed on a center of the upper body 1120. The exhaust hole 1122 exhausts an atmosphere of the treating space 1110. A plurality of inflow holes 1124 are provided to be spaced apart, and arranged to surround the exhaust hole 1122. The inflow holes 1124 introduce an outside air flow into the treating space 1110. According to an example, the inflow hole 1124 may be four and the outside air flow may be air.

Alternatively, the inflow holes 1124 may be provided in three or more than five, or the outside air flow may be an inert gas.

The lower body 1140 is provided in a cylindrical shape having an open upper portion. The lower body 1140 is positioned below the upper body 1120. The upper body 1120 and the lower body 1140 are positioned to face each other in a vertical direction. The upper body 1120 and the lower body 1140 are combined with each other to form a treating space 1110 therein. The upper body 1120 and the lower body 1140 are positioned so that the central axis of the upper body 1120 and the lower body 1140 are aligned in the vertical direction. The lower body 1140 may have the same diameter with the upper body 1120. That is, an upper end of the lower body 1140 may be positioned at least corresponds to a lower end of the upper body 1120.

One of the upper body 1120 and the lower body 1140 is moved to an open position and a blocking position by a lifting member 1130, and the other is fixed. An embodiment of the inventive concept describes that the position of the lower body 1140 is fixed and the upper body 1120 is moved. The open position is a position where the upper body 1120 and the lower body 1140 are spaced apart from each other to open the treating space 1110. The blocking position is a position where the treating space 1110 is sealed from an outside by the lower body 1140 and the upper body 1120.

A sealing member 1160 is positioned between the upper body 1120 and the lower body 1140. The sealing member 1160 allows the treating space to be sealed from the outside when the upper body 1120 and the lower body 1140 are contacted. The sealing member 1160 may be provided in an annular ring shape. The sealing member 1160 may be fixedly coupled to the upper end of the lower body 1140.

The supporting unit 1300 supports the substrate ‘W’ in the treating space. The supporting unit 1300 comprises a supporting plate 1320, a lift pin 1340, a supporting pin 1360, and a cooling unit 900.

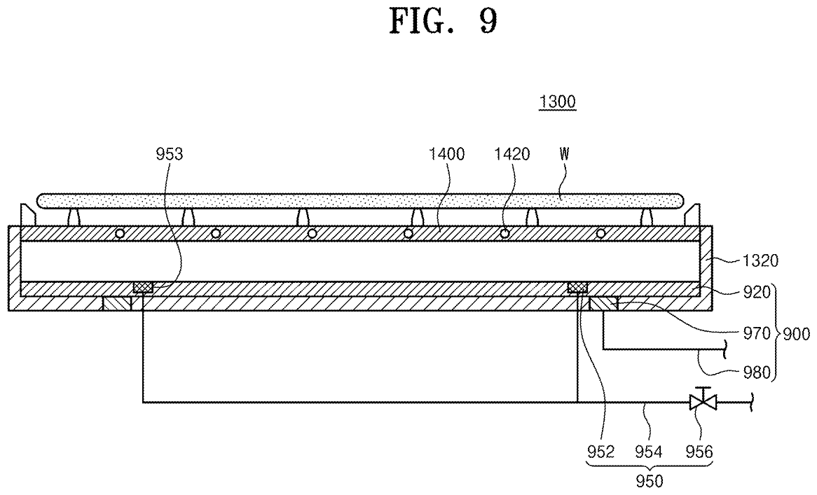

FIG. 8 is a plan view showing the supporting unit of FIG. 7 Referring to FIG. 7 and FIG. 8, the supporting plate 1320 is provided in a circular plate shape. An upper surface of the supporting plate 1320 has a greater diameter than the substrate ‘W’.

When viewed from above, lift holes 1322 are arranged to surround the center of the upper surface of the supporting plate 1320. Each of the lift holes 1322 is arranged to be spaced apart from each other along a circumferential direction.

The lift pin 1340 moves up and down the substrate ‘W’ on supporting plate 1320. A plurality of lift pins 1340 are provided, and each lift pin 1340 is provided in the shape of a pin facing in a vertical direction. Lift pins 1340 are located in each of the lift hole 1322. A driving member (not shown) moves each lift pin 1340 between a moving-up position and a moving-down position. The driving member (not shown) may be a cylinder.

A supporting pin 1360 prevents the substrate ‘W’ from directly making contact with a seating surface the supporting plate 1320. The supporting pin 1360 is provided in the shape of a pin having a longitudinal direction parallel to that of the lift pin 1340. A plurality of supporting pins 1360 are provided. Each supporting pin 1360 may be fixedly mounted on the supporting plate 1320. The supporting pins 1360 protrude upward from the supporting plate 1320. An upper end of the supporting pin 1360 has a contact surface directly contact with a bottom surface of the substrate ‘W’, and the contact surface of the supporting pin 1360 may have a convex-up shape. Accordingly, a contact area between the supporting pin 1360 and the substrate ‘W’ may be minimized.

A guide 1380 guides the substrate ‘W’ so that the substrate ‘W’ is in a normal position. The guide 1380 has a diameter greater than the diameter of the substrate ‘W’. The inner surface of the guide 1380 is inclined downward as it approaches the central axis of the supporting plate 1320. Accordingly, the substrate ‘W’ slides down to the normal position along the inclined surface of the guide 1380. In addition, the guide 1380 can prevent an air from flowing through between the substrate ‘W’ and the supporting plate 1320.

A heater member 1400 heats the substrate ‘W’ placed on supporting plate 1320. The heater member 1400 is positioned under the substrate ‘W’ placed on supporting plate 1320. The heater member 1420 comprises a plurality of heaters 1420. The heaters 1420 are positioned inside the supporting plate 1320.

The heaters 1420 heat different regions of the supporting surface. When viewed from above, heaters 1420 may define a plurality of heating zones in the supporting plate 1320. Each heater 1420 is independently adjustable in temperature. For example, the heating zone may be 15. The temperature of each heating zone is measured by a measuring member (not shown). The heaters 1420 may be printed patterns or heating wires. The heater member 1400 may heat the supporting plate 1320 to a process temperature.

The exhaust unit 1500 forcibly exhausts the inside of the treating space 1110. The exhaust unit 1500 comprises an exhaust pipe 1530 and a guide plate 1540. The exhaust pipe 1530 has a pipe shape in which the longitudinal direction is perpendicular to the vertical direction. The exhaust pipe 1530 is positioned to penetrate an upper wall of the upper body 1120. According to an example, the exhaust pipe 1530 can be positioned to be inserted into the exhaust hole 1122. That is, a lower end of the exhaust pipe 1530 is positioned in the treating space 1110, and an upper end of the exhaust pipe 1530 is positioned outside the treating space 1110. A decompression member 1560 is connected to the upper end of the exhaust pipe 1530. The decompression member 1560 decompresses the exhaust pipe 1530. Accordingly, an atmosphere of the treating space 1110 is exhausted sequentially through a through-hole 1452 of the guide plate and the exhaust pipe 1530.

The guide plate 1540 has a plate shape having the through-hole 1452 in the center. The guide plate 1540 has a circular plate shape extended from a lower end of the exhaust pipe 1530. The guide plate 1540 is fixedly coupled to the exhaust pipe 1530 so that the through-hole 1452 and the interior of the exhaust pipe 1530 communicate with each other. The guide plate 1540 faces the supporting surface of the supporting plate 1320 at the upper end of the supporting plate 1320. The guide plate 1540 is positioned higher than the lower body 1140. According to an example, the guide plate 1540 may be positioned at a height corresponding to the upper body 1120. When viewed from above, the guide plate 1540 is positioned to overlap with the inflow hole 1124 and a diameter of the guide plate is spaced apart from an inner surface of the upper body 1120. Accordingly, a gap is made between a side end of the guide plate 1540 and the inner surface of the upper body 1120, and the gap is provided in a flow path through which the air flow introduced through the inflow hole 1124 is supplied to the substrate ‘W’.

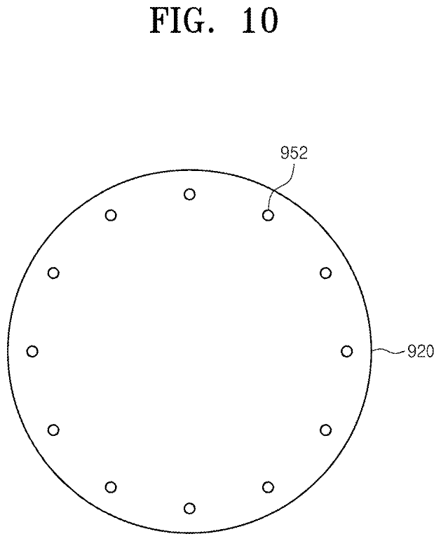

Hereinafter, referring to FIG. 9 and FIG. 10, the cooling unit will be described. FIG. 9 is a cross-sectional view showing the supporting unit of FIG. 7, and FIG. 10 is a plan view of the cooling plate 920 when viewed from above.

Referring to FIG. 9 and FIG. 10, the cooling unit 900 comprises a cooling plate 920, a driver 970, and a gas supply member 950. The cooling unit 900 cools the supporting plate 1320. The supporting plate 1320 is provided with a plate-shaped heater member 1400 comprising heaters 1420.

The cooling plate 920 is spaced apart from the heater member 1400. The nozzle 952 is provided to the cooling plate 920 and supplies cooling gas to the bottom surface of the heater member 1400. In one example, a plurality of the nozzle 952 may be arranged to be spaced apart along the circumferential direction of the cooling plate 920.

The driver 970 moves the cooling plate 920. In one example, the driver 970 is provided in a motor. Alternatively, the driver 970 is provided in a cylinder.

The driver 970 moves the cooling plate 920 between a standby position spaced a first distance apart from the heater member 1400 and a cooling position spaced a second distance apart from the heater member 1400. The second distance is provided in a distance shorter than the first distance.

When viewed from above, the cooling plate 920 is positioned to overlap the heater member 1400 in the standby position and the cooling position. Accordingly, the cooling plate 920 is provided to cool a whole surface of the heater member 1400.

In one example, the cooling plate 920 has a mounting groove 953 formed on an upper surface thereof, and the nozzle 952 is disposed in the mounting groove 953. In one example, a plurality of mounting grooves 953 are provided. For example, the plurality of mounting grooves 953 are provided along the circumferential direction of the cooling plate 920.

The gas supply member 950 supplies cooling gas into the mounting groove 953. The gas supply member 950 comprises a gas supply line 954, a control valve 956, and a nozzle 952. The gas supply member 950 supplies cooling gas into the nozzle 952. In one example, gas is air. The gas supply line 954 supplies cooling gas to the nozzle 952. The control valve 956 controls the flow rate of cooling gas supplied from a gas supply source (not shown) to the gas supply line 954.

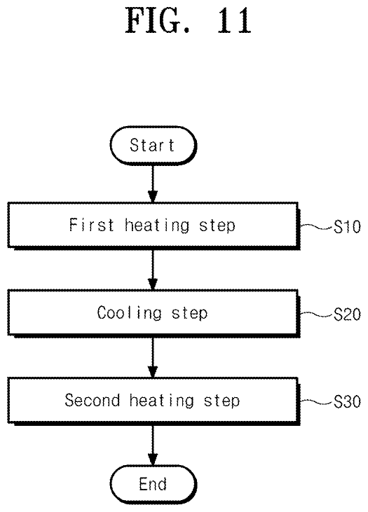

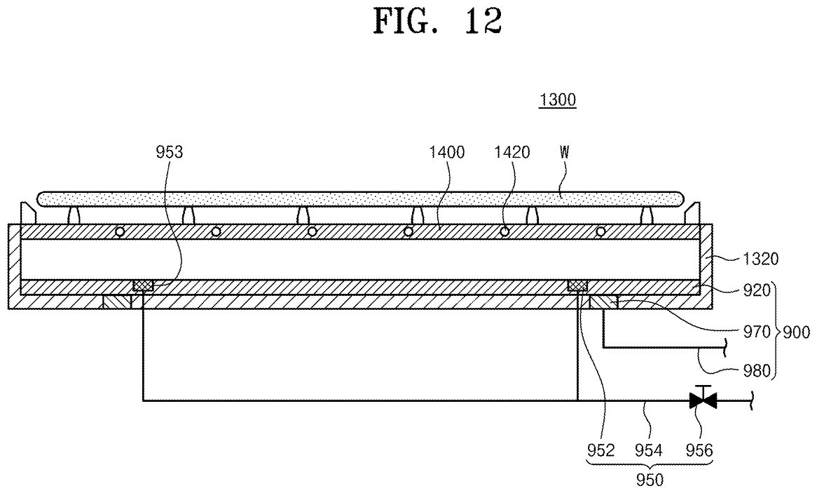

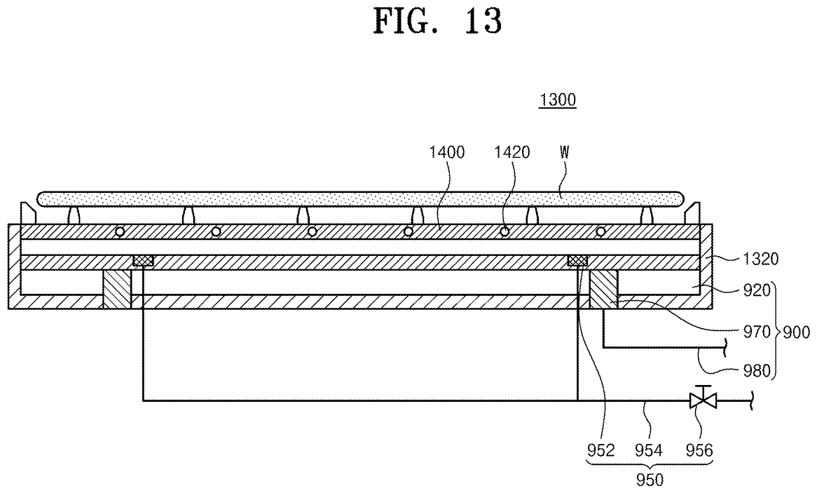

Hereinafter, a method for treating the substrate of the inventive concept will be described with reference to FIG. 11 to FIG. 13. FIG. 11 is a flow chart showing a method for treating the substrate, FIG. 12 and FIG. 13 are cross-sectional view showing the cooling plate moving according to an embodiment of the inventive concept.

Referring to FIG. 11, the method for treating the substrate of the inventive concept comprises a first heating step S10, a cooling step S20, and a second heating step S30. An example of the inventive concept comprises the cooling step S20 for treating a preceding substrate to the first temperature in the first heating step S10, and for treating a subsequent substrate to the second temperature in the second heating step S30.

In the first heating step S10, the supporting plate 1320 heats the substrate at the first temperature. At this time, as shown in FIG. 12, the cooling plate 920 is positioned at a standby position spaced the first distance apart from the heater member 1400.

Thereafter, in the cooling step S20, cooling gas is supplied to the supporting plate 1320 for cooling the supporting plate 1320 to a predetermined temperature. In the cooling step S20, the cooling gas is supplied to the bottom surface of the heater member 1400 through the gas supply member 950, and a temperature of the supporting plate 1320 is descended. The cooling step S20 continues until a temperature of the supporting plate 1320 becomes the second temperature which is lower than the first temperature.

For the cooling step S20, the cooling plate 920 is moved in a direction toward the heater member 1400. As shown in FIG. 13, the cooling plate 920 is positioned at a cooling position spaced a second distance apart from the heater member 1400 in the first heating step. The second distance is provided in a distance shorter than the first distance.

After the cooling step S20, the second heating step S30 is started. In the second heating step S30, the supporting plate 1320 treats the substrate at the second temperature which is lower than the first temperature. For the second heating step S30, the cooling plate 920 is returned to the standby position spaced a first distance apart from the heater member 1400.

According to the inventive concept, as the cooling unit 900 maintains a predetermined distance from the heater member 1400 in the first heating step S20 or the second heating step S30, an influence of the cooling unit 900 with respect to the heater member 1400 can be reduced when the substrate is heated, thereby minimizing the heat loss of the heater member 1400.

According to the inventive concept, as the cooling plate 920 is provided close to the heater member 1400 in the cooling step S20, it is easy to maintain a flow rate of the cooling gas discharged from the nozzle 952.

According to the inventive concept, as the cooling plate 920 is provided close to the heater member 1400 in the cooling step S20, cooling gas can be directly provided to the bottom surface of the heater member 1400 from the nozzle 952, thereby shortening the cooling time.

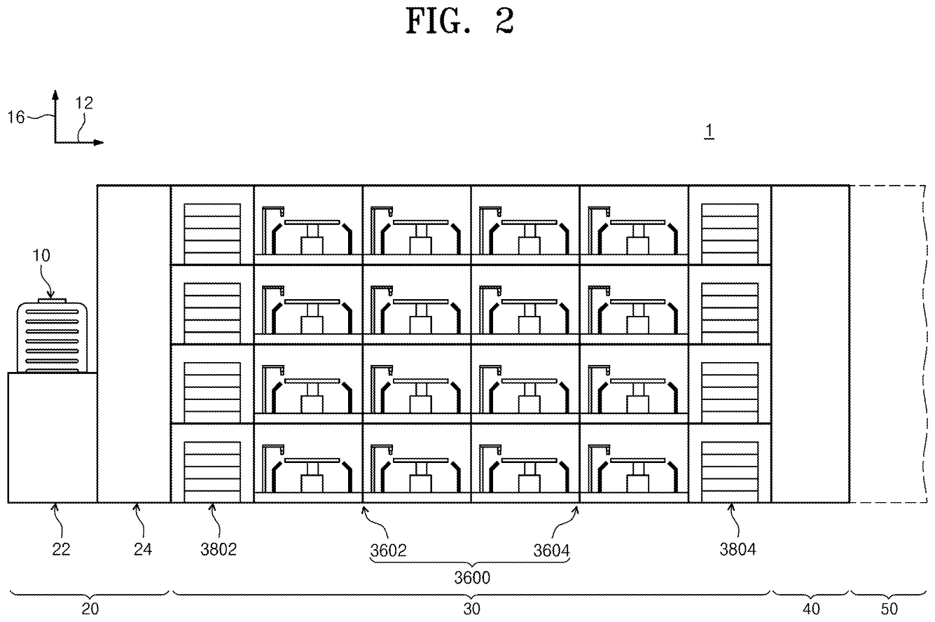

Referring again to FIG. 2 and FIG. 3, a plurality of buffer chambers 3800 are provided. Some 3802 of buffer chambers 3800 are disposed between the index module 20 and the transferring chamber 3400. Hereinafter, those buffer chamber 3802 are referred to as front buffer 3802. A plurality of the front buffers 3802 are provided and stacked on each other in the vertical direction. Others 3804 of the buffer chambers 3800 are disposed between the transferring chamber 3400 and the interface module 40. Hereinafter, those buffer chambers 3804 are referred to as rear buffers 3804. A plurality of the rear buffers 3804 are provided and stacked on each other in the vertical direction. The front buffers 3802 and the rear buffers 3804 temporarily store a plurality of substrates ‘W’. The substrate ‘W’ stored in the front buffer 3802 is introduced and withdrawn by the index robot 2200 and the transferring robot 3422. The substrate ‘W’ stored in the rear buffer 3804 is introduced and withdrawn by the transferring robot 3422 and a first robot 4602.

The developing block 30b has the heat treating chamber 3200, the transferring chamber 3400, and the liquid treating chamber 3600. Since the heat treating chamber 3200, the transferring chamber 3400, and the liquid treating chamber 3600 in the developing block 30b have a structure and an arrangement substantially similar to those of the heat treating chamber 3200, the transferring chamber 3400, and the liquid treating chamber 3600 in the coating block 30a, the details thereof will be omitted. However, all the liquid treating chambers 3600 in the developing block 30b supply the same developing liquid such that the substrate ‘W’ is subject to the developing treatment.

The interface module 40 connects the treating module 30 with an external exposing apparatus 50. The interface module 40 comprises an interface frame 4100, an additional process chamber 4200, an interface buffer 4400, and a transferring member 4600.

An upper end of the interface frame 4100 may be provided in a fan filter unit forming a descending air flow therein. The additional process chamber 4200, the interface buffer 4400, and the transferring member 4600 are arranged inside the interface frame 4100. Before the substrate ‘W’, which has been processed in the coating block 30a, is transferred to the exposing apparatus 50, the additional process chamber 4200 may perform a predetermined additional process. Alternatively, before the substrate ‘W’, which has been processed by the exposing apparatus 50, is transferred to the developing block 30b, the additional process chamber 4200 may perform a predetermined additional process According to an example, the additional process may be an edge exposing process that exposes an edge region of the substrate ‘W’, an upper surface cleaning process that cleans an upper surface of the substrate ‘W’, or a cleaning process that cleans the bottom surface of the substrate ‘W’. A plurality of additional process chambers 4200 may be provided, which may be provided to be stacked each other. The additional process chambers 4200 may all be provided to perform the same process. Alternatively, some of the additional process chambers 4200 may be provided to perform different processes.

The interface buffer 4400 provides a space where the substrate ‘W’ temporarily remains during a transfer. The substrate ‘W’ is transferred among the coating block 30a, the additional process chamber 4200, the exposing apparatus 50, and the developing block 30b. A plurality of interface buffers 4400 may be provided, and a plurality of interface buffers 4400 may be provided to be stacked on each other.

According to an exemplary embodiment of the inventive concept, the additional process chamber 4200 may be disposed on one side of the transferring chamber 3400 on the basis of the longitudinal direction of the transferring chamber 3400, and an interface buffer 4400 may be disposed at the other side of the transferring chamber 3400.

A transferring member 4600 transfers the substrate ‘W’ among the coating block 30a, the additional process chamber 4200, the exposing apparatus 50, and the development block 30b. The transferring member 4600 may be provided in one or a plurality of robots. According to an example, the transferring member 4600 has a first robot 4602 and a second robot 4606. The first robot 4602 transfers the substrate ‘W’ among the coating block 30a, the additional process chamber 4200, and the interface buffer 4400, and the interface robot 4606 transfers the substrate ‘W’ between the interface buffer 4400 and the exposing apparatus 50, and the second robot 4604 can be provided to transfer the substrate ‘W’ between the interface buffer 4400 and the developing block 30b.

The first robot 4602 and the second robot 4606 may comprise a hand in which the substrate ‘W’ is positioned respectively, and the hand 3420 may be provided to be movable forward and backward, and rotatable about the third direction 16, and movable along the third direction 16.

The hand of the index robot 2200, the first robot 4602, and the second robot 4606 may all be provided in the same shape as the hand 3420 of the transferring robots 3422, 3424. Alternatively, the hand of the robot transferring the substrate ‘W’ directly with the transferring plate 3240 of the heat treating chamber is provided in the same shape as the hand 3420 of the transfer robots 3422, 3424, and the hand of the other robot may be provided in a different shape.

According to an example, the index robot 2200 may be provided to directly transfer the substrate ‘W’ with a heating apparatus 3230 of a front heat treating chamber 3200 provided in the coating block 30a.

In addition, a transferring robot 3422 provided in the coating block 30a and the developing block 30b may be provided to directly transfer the substrate ‘W’ with a transferring plate 3420 positioned in the heat treating chamber 3200.

A treating block of the substrate treating apparatus 1 described above is described as performing a coating treating process and a developing treating process. However, the substrate treating apparatus 1 may comprise only the index module 20 and the treating block 37 without the interface module. In this case, the treating block 37 performs only the coating treating process, and a film applied on the substrate ‘W’ may be a Spin On Hardmask (SOH).

The above description has been made for the illustrative purpose. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to limit the inventive concept to the disclosed embodiments. Furthermore, it should be construed that the attached claims include other embodiments.

What is claimed is:

1. A supporting unit comprising:
a supporting plate supporting a substrate;
a heater member provided in the supporting plate and heating the substrate; and
a cooling unit provided below the heater member and cooling the supporting plate,
wherein the cooling unit comprises:
a cooling plate spaced apart from the heater member;
a nozzle provided in the cooling plate, and supplying cooling gas to a bottom surface of the heater member; and
a driver moving the cooling plate between a standby position spaced a first distance apart from the heater member and a cooling position spaced a second distance apart from the heater member,
wherein the second distance is shorter than the first distance.

2. A supporting unit of claim 1, wherein
when viewed from above, the cooling plate overlaps with the heater member in the standby position and the cooling position.

3. A supporting unit of claim 1,
wherein the cooling plate has a mounting groove on an upper surface thereof,
wherein the nozzle is arranged in the mounting groove.

4. A supporting unit of claim 3, wherein
the cooling unit further comprises:
a gas supply member supplying the cooling gas into the mounting groove.

5. A supporting unit of claim 1, wherein
the driver is provided in a motor.

6. A supporting unit of claim 1, wherein
the driver is provided in a cylinder.

7. An apparatus for treating a substrate, the apparatus comprising:
a housing having a process space therein; and
a supporting unit supporting a substrate in the process space,
wherein the supporting unit comprises:
a supporting plate supporting the substrate;
a heater member provided in the supporting plate and heating the substrate; and
a cooling unit provided below the heater member and cooling the supporting plate,
wherein the cooling unit comprises:
a cooling plate spaced apart from the heater member;
a nozzle provided in the cooling plate, and supplying a cooling gas to a bottom surface of the heater member; and
a driver moving the cooling plate between a standby position spaced a first distance apart from the heater member and a cooling position spaced a second distance apart from the heater member,
wherein the second distance is shorter than the first distance.

8. The apparatus of claim 7, wherein
the cooling plate overlaps with the heater member in the standby position and the cooling position when viewed from above.

9. The apparatus of claim 7,
wherein the cooling plate has a mounting groove on an upper surface,
wherein the nozzle is arranged in the mounting groove.

10. The apparatus of claim 9, wherein
the cooling unit comprises:
a gas supply member supplying the cooling gas into the mounting groove.

11. The apparatus of claim 7, wherein
the driver is provided in a motor.

12. The apparatus of claim 7, wherein
the driver is provided in a cylinder.

13. The apparatus of claim 7, wherein
the cooling gas is air.

14. The apparatus of claim 7, wherein
treating the substrate comprises bake-treating the substrate.
